(19) United States
(12) Patent Application Publication
(10) Pub. No.: US 2010/0164039 A1
(43) Pub. Date: Jul. 1, 2010

(54) IMAGE SENSOR AND METHOD FOR MANUFACTURING THE SAME

(76) Inventor: Il-Ho Song, Cheongju-si (KR)

Correspondence Address: SHERR & VAUGHN, PLLC, 620 HERNDON PARKWAY, SUITE 320, HERNDON, VA, 20170, US

(21) Appl. No.: 12/649,251

(22) Filed: Dec. 29, 2009

(30) Foreign Application Priority Data
Dec. 31, 2008 (KR) 10-2008-0138294

(51) Int. Cl. H01L 31/0232; H01L 21/30; H01L 31/18

(52) U.S. Cl. 257/432; 438/69; 438/70; 257/E31.127; 257/E21.211

(57) ABSTRACT

An image sensor includes a photodiode arranged over a semiconductor substrate, a core layer for an optical waveguide, to allow incident light to move toward the photodiode, the core layer being arranged over the photodiode, a clad layer for the optical waveguide, having a lower refractive index than the core layer to reflect the incident light to the photodiode, the clad layer being arranged over the side core layer, and a dielectric layer arranged over a side of the clad layer. An optical waveguide having a uniform refractive index and a flat light-reflection surface can be formed using semiconductor materials such as InP, InGaAsP, SiO2, SiON and PMMA. Furthermore, the optical waveguide can control a refractive index and thus reduce light loss, and a buffer layer can be simply formed by using a polymer.

The present application claims priority under 35 U.S.C. 119 to Korean Patent Application No. 10-2008-0138294 (filed on Dec. 31, 2008), which is hereby incorporated by reference in its entirety.

### BACKGROUND

In recent years, unit pixel sizes of CMOS image sensors have decreased in order to realize high-scale integration. However, in most cases, this means a light-accepting region, the photodiode (PD), decreases in size. Accordingly, to overcome reduction of such an efficient light-accepting region, a microlens is used in each unit pixel to improve sensitivity.

Meanwhile, light diffraction and scattering resulting from additional structures such as metal lines present in a light path which extends from the microlens to the PD cause crosstalk, thus leading to sensitivity and other problems. In an attempt to solve these problems, a region which extends from the microlens to the PD is filled with a material having a high refractive index to form an optical waveguide structure. This allows converged light from the microlens to undergo total internal reflection through the optical waveguide and to be suitably transferred to the PD.

A related method for forming an optical waveguide is to implant ions into an intermetal dielectric layer (IMDL) and thus induce variation in refractive index. However, the optical waveguide formed by ion-implantation includes a core layer and a clad layer whose refractive indexes are different from each other and whose light-reflection surfaces are non-uniform, thus disadvantageously increasing light loss.

Prior to the description of embodiments, the principle of an optical waveguide will be described with reference to the annexed drawing. FIG. 1 is a view illustrating the principle of total reflection.

The term “optical waveguide” refers to a passage which includes a medium having a high refractive index n1, i.e., core 20 and a medium having a low refractive index n2, i.e., clad 10, surrounding the core 20, to guide light to a target position by total internal reflection occurring on the interface between the core 20 and the clad 10. The difference in refractive index enables formation of the optical waveguide.

For total internal reflection to occur in an optical waveguide, an incident angle θ of incident light 30 should be lower than a total internal reflection angle θT. The total internal reflection angle θT depends on refractive indexes n1 and n2 of the two mediums 20 and 10, as shown in Equation 1 below:

$$sin {θ}_{T} = \frac{n 2}{n 1} \qquad ( 1 )$$

Meanwhile, such an optical waveguide may be used to allow light passing through color filters to move to photodiodes arranged therebelow in CIS.

### SUMMARY

Embodiments relate to a semiconductor device and a method for manufacturing the same. More specifically, embodiments relate to an image sensor and a method for manufacturing the same. Embodiments relate to an image sensor and a method for manufacturing the same, wherein an optical waveguide is made of semiconductor materials to reduce light loss.

Embodiments relate to an image sensor which may include: a photodiode arranged over a semiconductor substrate; a core layer for an optical waveguide, to guide incident light toward the photodiode, the core layer being arranged over the photodiode; a clad layer for the optical waveguide, having a lower refractive index than a refractive index of the core layer to reflect the incident light to the photodiode, the clad layer being arranged over a side of the core layer; and a dielectric layer arranged over the side of the clad layer.

Embodiments relate to an image sensor which may include: a photodiode arranged over a semiconductor substrate; a core layer for an optical waveguide, to guide incident light toward the photodiode, the core layer arranged over the photodiode; and a dielectric layer serving as a clad layer for the optical waveguide, having a refractive index lower than a refractive index of the core layer, to reflect the incident light to the photodiode, the clad layer being arranged over a side of the core layer.

Embodiments relate to a method for manufacturing an image sensor, which may include: forming a photodiode over a semiconductor substrate; forming a dielectric layer over the semiconductor substrate including the photodiode; forming a photosensitive film mask over the dielectric layer to expose an optical waveguide region; etching the dielectric layer using the photosensitive film mask as an etching mask to form an opening to expose the photodiode; forming a clad layer of the optical waveguide, having a first refractive index, such that the clad layer exposes the top of the photodiode and covers an inner wall of the opening; and forming a core layer for the optical waveguide, having a second refractive index higher than the first refractive index, over the top of the photodiode and the clad layer.

Embodiments relate to a method for manufacturing an image sensor, which may include: forming a photodiode over a semiconductor substrate; forming a dielectric layer having a first refractive index as a clad layer over the semiconductor substrate including the photodiode; forming a photosensitive film mask over the dielectric layer to expose an optical waveguide region; etching the dielectric layer using the photosensitive film mask as an etching mask to form an opening to expose the photodiode; and filling the opening with a core layer for the optical waveguide, the core layer having a second refractive index higher than the first refractive index.

### DRAWINGS

FIG. 1 is a view illustrating the principle of total reflection.

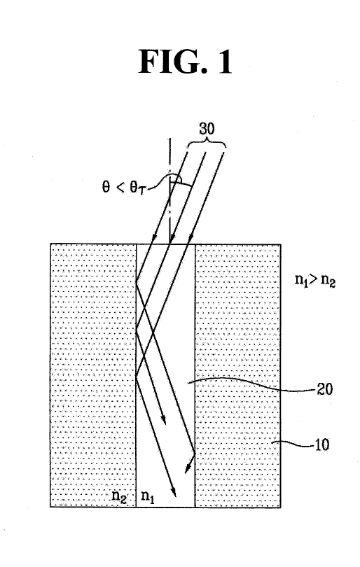

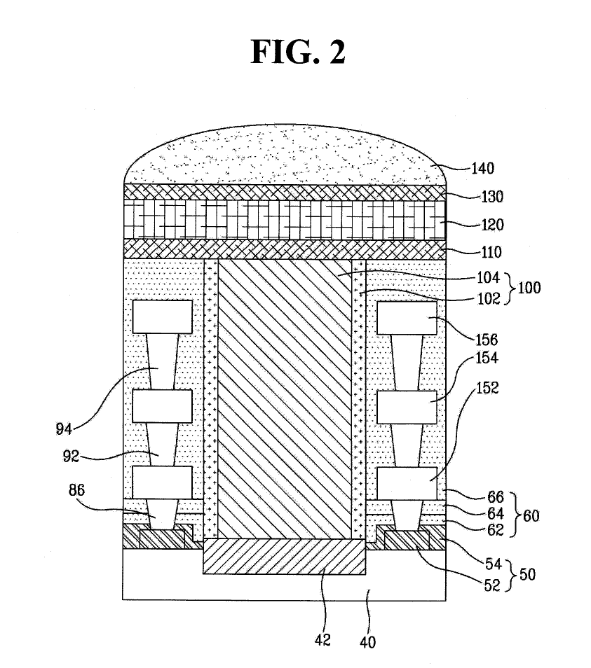

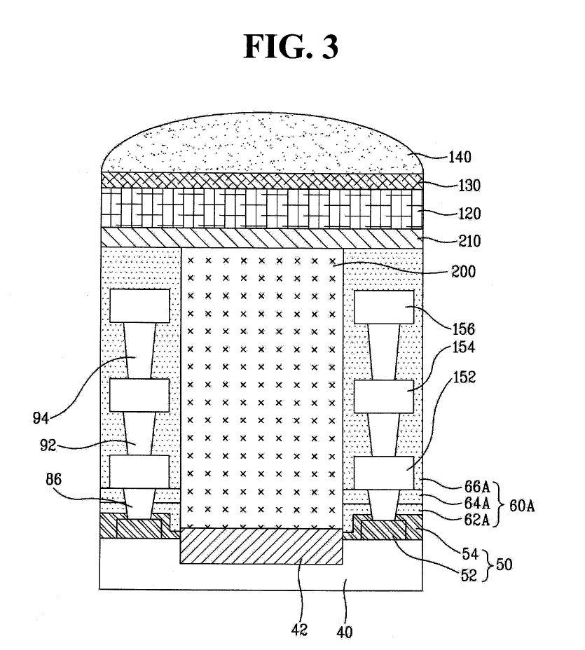

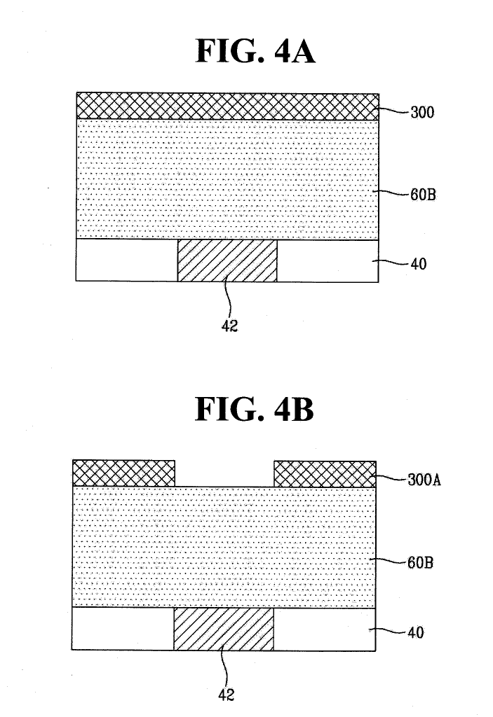

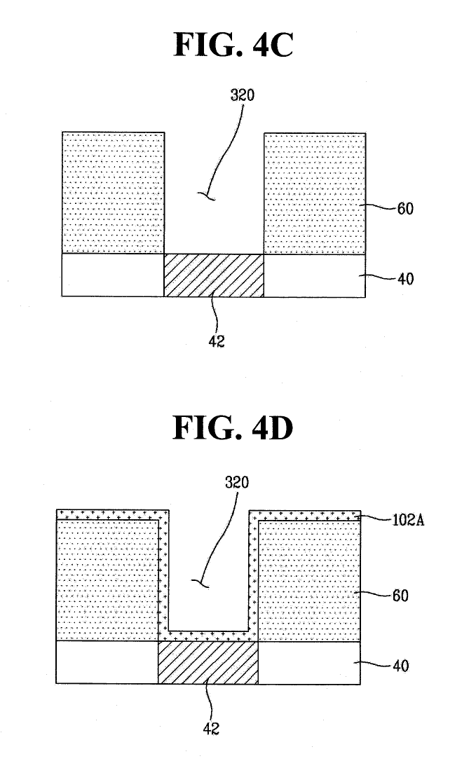

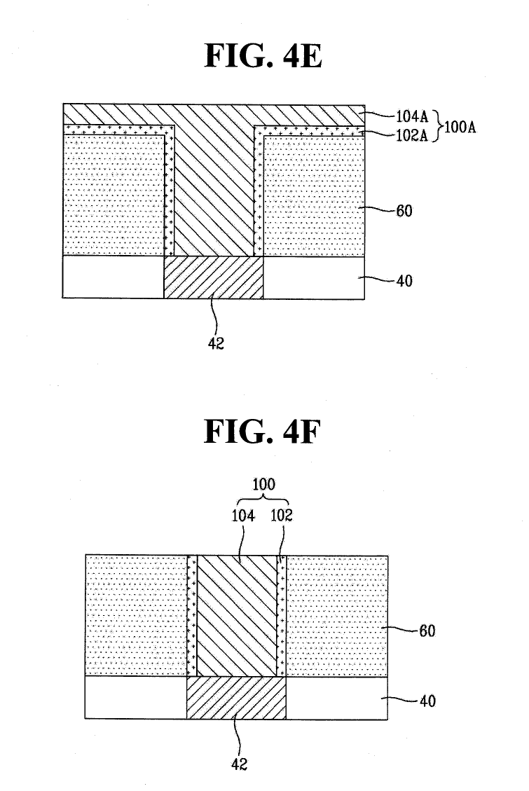

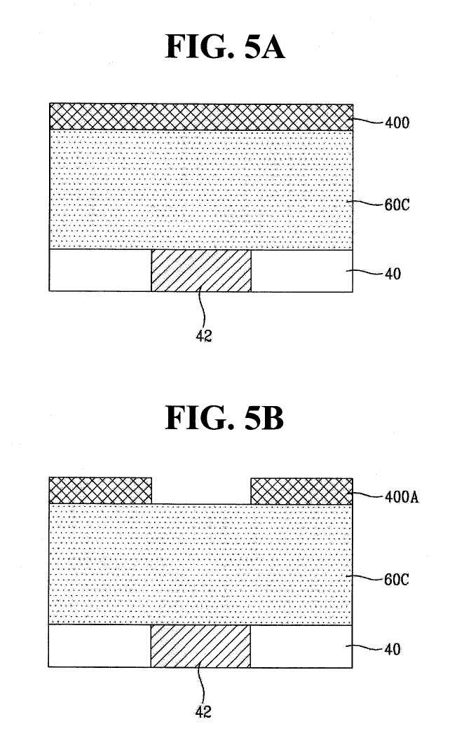

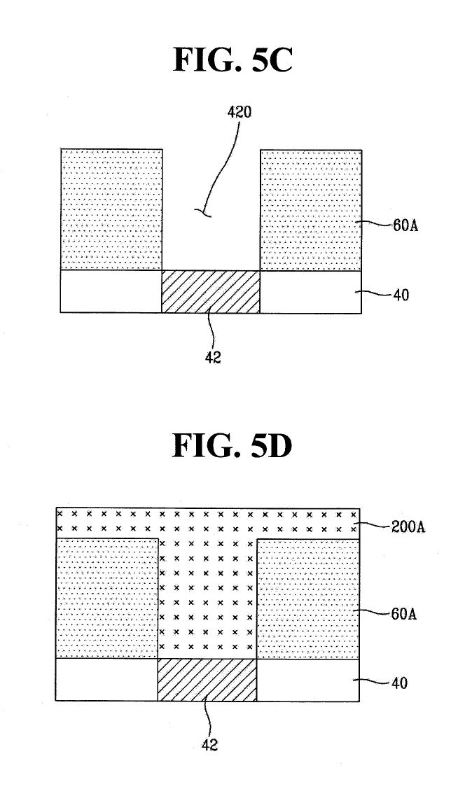

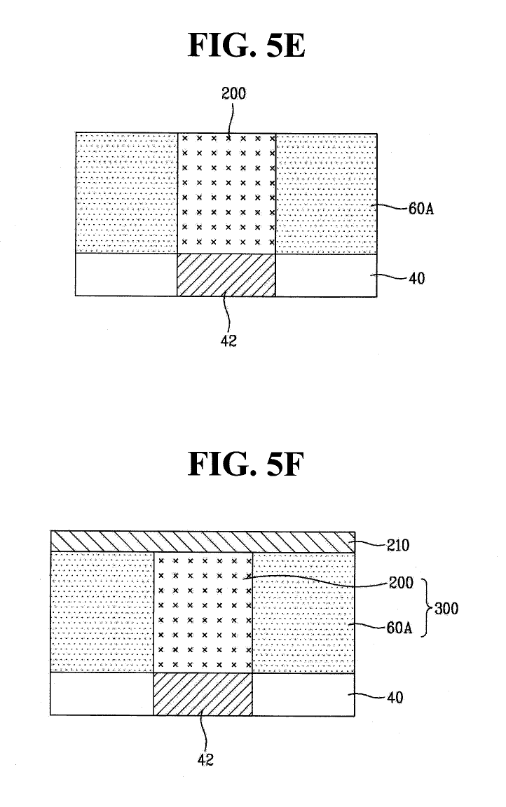

Example FIG. 2 is a sectional view illustrating an image sensor according to embodiments.

Example FIG. 3 is a sectional view illustrating an image sensor according to embodiments.

Example FIGS. 4A to 4F are sectional process views illustrating a method for manufacturing an image sensor according to embodiments.

Example FIGS. 5A to 5F are sectional process views illustrating a method for manufacturing an image sensor according to embodiments.

### DESCRIPTION

Hereinafter, image sensors according to embodiments will be illustrated with reference to the annexed drawings. Example FIG. 2 is a sectional view illustrating an image sensor according to embodiments.

Referring to example FIG. 2, a photodiode 42 may be arranged over a semiconductor substrate 40. An optical waveguide 100 may include a core layer 104 and a clad layer 102. The core layer 104 allows light which enters vertically or at an angle to a microlens 140 and passes through a color filter array (CFA) 120 to move to the photodiode 42. For this purpose, the core layer 104 may be arranged over the photodiode 42. The clad layer 102 reflects incident light, which is not directed toward the photodiode 42 and deviates the same, to the photodiode 42. For this purpose, the clad layer 102 has a lower refractive index than that of the core layer 104 and is arranged over the side of the core layer 104.

In embodiments, the clad layer 102 may be made of InP and the core layer 104 may be made of InGaAsP having a greater refractive index than that of InP. In other embodiments, the clad layer 102 may be made of SiO₂ and the core layer 104 may be made of SiON having a greater refractive index than that of SiO₂. The refractive index of SiO₂ is about 0.144 and the refractive index of SiON is not less than 1.46.

A dielectric layer 60 may be arranged over the side of the clad layer 102 and over the semiconductor substrate 40. The image sensor of embodiments is not limited to constituent components shown in example FIG. 2 and may be constituted in various forms.

First, an understructure 50, made of polysilicon, including a gate electrode 54 and an insulating film 52, may be arranged over the semiconductor substrate 40. A plurality of interlayer dielectric films 62, 64 and 66 may be arranged over the understructure 50. A plurality of metal patterns 152, 154 and 156 may be arranged over the dielectric layer 60. In addition, a contact 86 to connect the understructure 50 to the metal pattern 152 passes through the interlayer dielectric films 62 and 64. A via 92 to interconnect the metal patterns 152 and 154 and a via 94 to interconnect the metal patterns 154 and 156 may be arranged over the interlayer dielectric film 66.

A buffer layer 110, that is, a passivation layer 110 may be arranged over the entire surface of the core layer 104, the clad layer 102 and the dielectric layer 60. The buffer layer 110 may be made of a dielectric material. A color filter array 120 may be arranged over the buffer layer 110. The color filter array 120 includes red R, green G and blue B color filters. A planarizing layer 130 may be arranged over the color filter array 120. The planarizing layer 130 serves to planarize the color filter array 120 to stably place the microlens 140 thereon. The microlens 140 may be arranged over the planarizing layer 130 such that it faces the photodiode 42. The microlens 140 may be a graded index microlens.

As shown in example FIG. 2, unlike related image sensors, the image sensor of embodiments may include the optical waveguide 100, including of the clad layer 102 and the core layer 104 made of semiconductor materials such as InP 102 and InGaAsP 104, or SiO2 102 and SiON 104, respectively. Accordingly, the image sensor comprising an optical waveguide may be formed using semiconductor materials rather than ion-implantation as shown in example FIG. 2 can reduce light loss, while related image sensors using an optical waveguide formed by ion-implantation induce loss of a greater amount of light. In the optical waveguide according to embodiments, the core layer and the clad layer have identical refractive indexes to each other and a uniform light-reflection surface.

Example FIG. 3 is a sectional view illustrating an image sensor according to embodiments. In example FIGS. 2 and 3, the same or similar elements of the image sensor are denoted by the same reference numerals and an explanation thereof is omitted.

As shown in example FIG. 3, the optical waveguide of the image sensor may include a core layer 200 and a clad layer 60A. First, the core layer 200 allows light which enters a microlens 140 and a color filter array 120 to move to a photodiode 42. For this purpose, the core layer 200 may be arranged over the photodiode 42.

The clad layer 60A reflects incident light, which is not directed toward the photodiode 42 and deviates the same, to the photodiode 42. For this purpose, the clad layer 60A has a lower refractive index than that of the core layer 200 and may be arranged over the side of the core layer 200. In the image sensor shown in example FIG. 3, unlike the image sensor shown in example FIG. 2, the dielectric layer 60A serves as the clad layer. The dielectric layer 60A shown in example FIG. 3 includes three different dielectric layers 62A, 64A and 66A. These dielectric layers 62A, 64A and 66A may be identical to or different from one another, and have a refractive index lower than that of the core layer 200 to form the optical waveguide.

In embodiments, the core layer 200 may be made of photosensitive polymer, e.g., poly methyl methacrylate (PMMA). In embodiments, a buffer layer 210 may be arranged over the entire surface of the core layer 200 and the dielectric layer 60A. The buffer layer 210 may be made of highly permeable polyethylene.

Accordingly, the optical waveguide of the image sensor shown in example FIG. 3, unlike related optical waveguides of image sensors, comprises the core layer 200 made of highly permeable PMMA and the clad layer formed of the dielectric layer 60A. Since the optical waveguide may be formed using semiconductor materials, rather than ion-implantation, the core and clad layers may have the same refractive index and a flat light-reflection surface, as shown in example FIG. 3, thus advantageously reducing light loss. Hereinafter, a method for manufacturing image sensors according to embodiments will be illustrated with reference to the annexed drawings.

Example FIGS. 4A to 4F are sectional process views illustrating a method for manufacturing an image sensor according to embodiments. The optical waveguide 100 shown in example FIG. 2 may be formed by the method illustrated with reference to example FIGS. 4A to 4F. The method for manufacturing the image sensor is illustrated under the assumption that dielectric layers 62, 64 and 66 may be identical for convenience of illustration and embodiments are not limited thereto. In addition, this illustration may be focused on a manufacturing method of only the optical waveguide 100, to allow the image sensor of embodiments to be distinguished from related image sensors. That is, methods for manufacturing other elements may be well-known in the art and a detailed explanation thereof is omitted.

First, referring to example FIG. 4A, a photodiode 42 may be formed over a semiconductor substrate 40. For example, an ion-implantation mask to open a region, in which the photodiode 42 is formed, may be formed over the semiconductor substrate 40. Then, ions may be implanted using the ion-implantation mask over the semiconductor substrate 40 to form the photodiode 42, as shown in example FIG. 4A. Then, a dielectric layer 60B may be formed over the entire surface of the semiconductor substrate 40 including the photodiode 42. Then, the dielectric layer 60B may be coated with a photoresist 300.

Then, as shown in example FIG. 4B, the photoresist 300 may be patterned to form a photosensitive film mask 300A to expose an optical waveguide region. Referring to example FIG. 4C, the dielectric layer 60B may be dry-etched by reactive ion etching (RIB) using the photosensitive film mask 300A as an etching mask to form an opening 320 over the dielectric layer 60 such that the opening 320 exposes the photodiode 42.

Then, as shown in example FIGS. 4D to 4F, a clad layer 102 of the optical waveguide, having a first refractive index, exposing the top of the photodiode 42 and covering an inner wall of the opening 320 may be formed. Then, a core layer 104 of the optical waveguide, having a second refractive index higher than the first refractive index, may be formed over the top of the photodiode 42 exposed during embedding of the opening 320, and over the clad layer 102.

For example, as shown in example FIG. 4D, a material (InP or SiO₂) 102A for the clad layer 102 having the first refractive index may be homogeneously deposited over the photodiode 42 and over the inner wall of the opening 320. For example, the deposition of the material 102A for the clad layer 102 may be carried out by chemical vapor deposition (CVD).

Then, as shown in example FIG. 4E, the material 102A may be etched such that the top of the photodiode 42 is exposed. Then, as shown in example FIG. 4E, a material (InGaAsP or SiON, 104A) for the core layer 104 may be homogeneously deposited, such that the material covers the top of the photodiode 42 and gap-fills the opening 32. For example, the deposition of the material 104A may be carried out by plasma enhanced chemical vapor deposition (PECVD). When the material 102A for the clad layer 102 is InP, the material 104A for the core layer 104 is InGaAsP, and when the material 102A for the clad layer 102 is SiO₂, the material 104A for the core layer 104 is SiON.

Then, as shown in example FIG. 4F, the material 104A for the core layer 104 and the material 102A for the clad layer 102 may be etched, until the top of the dielectric layer 60 is exposed. Then, as shown in example FIG. 2, a buffer layer 110 is formed over the entire surface of the core layer 104, the clad layer 102 and the dielectric layer 60.

Then, a color filter array 120 may be formed over the buffer layer 110. Then, a planarizing layer 130 may be formed over the color filter array 120. Then, a microlens 140 may be formed over the planarizing layer 130 such that the microlens 140 corresponds to the photodiode 42.

Example FIGS. 5A to 5F are sectional process views illustrating a method for manufacturing an image sensor according to embodiments. The optical waveguide 200 and 60A shown in example FIG. 3 may be formed by the method illustrated with reference to example FIGS. 5A to 5E, and the buffer layer 210 may be formed by the method illustrated with reference to example FIG. 5F. The method for manufacturing the image sensor is illustrated under the assumption that dielectric layers 62, 64A and 66A are identical for convenience of illustration and embodiments are not limited thereto. In addition, methods for forming only the optical waveguide 200 and 60A and the buffer layer 210, to allow the image sensor of this embodiment to be distinguished from related image sensors, are illustrated.

First, as shown in example FIG. 5A, a photodiode 42 is formed over a semiconductor substrate 40. For example, an ion-implantation mask to open a region, in which the photodiode 42 is formed, may be formed over the semiconductor substrate 40. Then, ions may be implanted using the ion-implantation mask over the semiconductor substrate 40 to form the photodiode 42, as shown in example FIG. 5A.

Then, a dielectric layer 60C having a first refractive index may be formed as a clad layer for an optical waveguide over the entire surface of the semiconductor substrate 40 including the photodiode 42. Then, a photoresist 400 may be coated over the dielectric layer 60C. Then, as shown in example FIG. 5B, the photoresist 400 may be patterned to form a photosensitive film mask 400A to expose an optical waveguide region.

Then, referring to example FIG. 5C, the dielectric layer 60C may be dry-etched by reactive ion etching (RIE) using the photosensitive film mask 400A as an etching mask to form an opening 420 over the dielectric layer 60C such that the opening 420 exposes the photodiode 42.

Then, as shown in example FIGS. 5D and 5E, a clad layer 200 for the optical waveguide, having a second refractive index higher than the first refractive index, may be homogeneously deposited, while embedding the exposed top of the photodiode 42 and the opening 420.

For example, as shown in example FIG. 5D, a material 200A for the core layer 200 may be formed, while embedding the exposed top of the photodiode 42 and the opening 420. Photosensitive polymer, PMMA, SU-8®, as the material 200A for the core layer 200 may be formed by spin coating.

Then, as shown in example FIG. 5E, the material 200A for the core layer 200 may be etched to form the core layer 200. Then, as shown in example FIG. 5F, a buffer layer 210 may be formed over the entire surface of the core layer 200 and the dielectric layer 60A. For example, the buffer layer 210 may be formed by coating polyethylene as a material for the buffer layer 210. As such, the buffer layer 210 can be simply formed using a polymer such as polyethylene, as compared to the related passivation layer 110 made of a dielectric material. Then, the formation order of the color filter array 120, the planarizing layer 130 and the microlens 140 shown in example FIG. 3 may be as mentioned above.

Unlike optical waveguides of related image sensors which are formed by ion-implantation and thus induce serious light loss, in accordance with the image sensor and the method for manufacturing the same, an optical waveguide having a uniform refractive index and a flat light-reflection surface can be formed using semiconductor materials such as InP, InGaAsP, SiO₂, SiON and PMMA. Furthermore, this optical waveguide can control a refractive index and thus reduce light loss, and a buffer layer can be simply formed using a polymer.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a photodiode arranged over a semiconductor substrate;
a core layer for an optical waveguide, to guide incident light toward the photodiode, the core layer being arranged over the photodiode;
a clad layer for the optical waveguide, having a lower refractive index than a refractive index of the core layer to reflect the incident light to the photodiode, the clad layer being arranged over a side of the core layer; and
a dielectric layer arranged over the side of the clad layer.

2. The apparatus of claim 1, wherein the clad layer is made of InP and the core layer is made of InGaAsP.

3. The apparatus of claim 1, wherein the clad layer is made of SiO₂ and the core layer is made of SiON.

4. An apparatus comprising:
a photodiode arranged over a semiconductor substrate;
a core layer for an optical waveguide, to guide incident light toward the photodiode, the core layer arranged over the photodiode; and
a dielectric layer serving as a clad layer for the optical waveguide, having a refractive index lower than a refractive index of the core layer, to reflect the incident light to the photodiode, the clad layer being arranged over a side of the core layer.

5. The apparatus of claim 4, wherein the core layer is made of a photosensitive polymer.

6. The apparatus of claim 5, wherein the core layer is made of poly methyl methacrylate.

7. The apparatus of claim 4, including:
a buffer layer arranged over the entire surface of the core layer and the dielectric layer;
a color filter array arranged over the buffer layer;
a planarizing layer arranged over the color filter array; and
a microlens arranged over the planarizing layer such that the microlens corresponds to the photodiode.

8. The apparatus of claim 7, wherein the buffer layer is made of polyethylene.

9. The apparatus of claim 1, including:
a buffer layer arranged over the entire surface of the core layer and the dielectric layer;
a color filter array arranged over the buffer layer;
a planarizing layer arranged over the color filter array; and
a microlens arranged over the planarizing layer such that the microlens corresponds to the photodiode.

10. A method comprising:
forming a photodiode over a semiconductor substrate;
forming a dielectric layer over the semiconductor substrate including the photodiode;
forming a photosensitive film mask over the dielectric layer to expose an optical waveguide region;
etching the dielectric layer using the photosensitive film mask as an etching mask to form an opening to expose the photodiode;
forming a clad layer of the optical waveguide, having a first refractive index, such that the clad layer exposes the top of the photodiode and covers an inner wall of the opening; and
forming a core layer for the optical waveguide, having a second refractive index higher than the first refractive index, over the top of the photodiode and the clad layer.

11. The method of claim 10, wherein the clad layer is made of InP and the core layer is made of InGaAsP.

12. The method of claim 10, wherein the clad layer is made of SiO₂ and the core layer is made of SiON.

13. A method comprising:
forming a photodiode over a semiconductor substrate;
forming a dielectric layer having a first refractive index as a clad layer over the semiconductor substrate including the photodiode;
forming a photosensitive film mask over the dielectric layer to expose an optical waveguide region;
etching the dielectric layer using the photosensitive film mask as an etching mask to form an opening to expose the photodiode; and
filling the opening with a core layer for the optical waveguide, the core layer having a second refractive index higher than the first refractive index.

14. The method of claim 13, wherein the core layer is made of a photosensitive polymer.

15. The method of claim 14, wherein the core layer is made of poly methyl methacrylate.

16. The method of claim 15, including forming a buffer layer over the entire surface of the core layer and the dielectric layer.

17. The method of claim 16, wherein the buffer layer is made of polyethylene.

18. The method of claim 16, including:
forming a color filter array over the buffer layer;
forming a planarizing layer over the color filter array; and
forming a microlens over the planarizing layer such that the microlens corresponds to the photodiode.

19. The method of claim 10, including forming a buffer layer over the entire surface of the core layer and the dielectric layer.

20. The method of claim 19, including:
forming a color filter array over the buffer layer;
forming a planarizing layer over the color filter array; and
forming a microlens over the planarizing layer such that the microlens corresponds to the photodiode.
